(19) United States
(12) Patent Application Publication
(10) Pub. No.: US 2012/0256675 A1
(43) Pub. Date: Oct. 11, 2012

(54) INPUT REFERENCE VOLTAGE GENERATING METHOD AND INTEGRATED CIRCUIT USING THE SAME

(75) Inventor: Jeong Hun LEE, Daejeon (KR)

(73) Assignee: HYNIX SEMICONDUCTOR INC., Icheon-si (KR)

(21) Appl. No.: 13/339,158

(22) Filed: Dec. 28, 2011

(30) Foreign Application Priority Data
Apr. 11, 2011 (KR) 10-2011-0033430

(51) Int. Cl. H03L 5/00

(52) U.S. Cl. 327/333

(57) ABSTRACT

An integrated circuit includes: a reference voltage generation unit configured to be driven in response to an enable signal, select one of a plurality of reference voltages generated by dividing a power supply voltage as an input reference voltage, and output the input reference voltage; and a reference voltage level compensation unit configured to be driven in response to the enable signal and change a level of the input reference voltage by an amount of change in a level of an external voltage.

### CROSS-REFERENCES TO RELATED APPLICATIONS

The present application claims priority under 35 U.S.C. 119(a) to Korean Application No. 10-2011-0033430, filed on Apr. 11, 2011, in the Korean intellectual property Office, which is incorporated herein by reference in its entirety set forth in full.

### BACKGROUND

Circuits included in an integrated circuit transmit and receive digital signals including data. A circuit receiving a digital signal compares a reference voltage with the digital signal through an input buffer including a differential amplifier-type comparator, and determines whether the digital signal is at a logic high level or logic low level.

The reference voltage is set to an intermediate value between a potential defining a logic high level and a potential defining a logic low level, and serves as an absolute voltage for determining the logic level of the inputted digital signal.

In general, a reference voltage generation circuit generates a reference voltage at an intermediate level between a power supply voltage VDD and a ground voltage VSS during a power-up period. After the power-up period is ended, the reference voltage generation circuit selects one of a plurality of levels as the level of the reference voltage, where the plurality of levels are generated through voltage division by a plurality of resistors. Therefore, the level of the reference level may be quickly set.

However, the reference voltage generation circuit operating in such a manner may cause an error in determining the logic level of the digital signal, when the level of the external voltage VDD or VSS applied from outside is changed.

### SUMMARY

An embodiment of the present invention relates to an integrated circuit which compensates for the level of an input reference voltage by changing the level of the input reference voltage by an amount of change in the level of an external voltage, thereby substantially preventing an error in determining a logic level of a digital signal. Furthermore, the integrated circuit may reduce a level setting time of an input reference voltage by reducing loading of an input reference voltage output terminal.

In one embodiment, an integrated circuit includes: a reference voltage generation unit configured to be driven in response to an enable signal, select one of a plurality of reference voltages generated by dividing a power supply voltage as an input reference voltage, and output the input reference voltage; and a reference voltage level compensation unit configured to be driven in response to the enable signal and change a level of the input reference voltage by an amount of change in a level of an external voltage.

Another embodiment includes a method comprising selecting one of a plurality of reference voltages generated by dividing a power supply voltage to arrive at an input reference voltage in response to an enable signal; and changing a level of the input reference voltage by an amount of change in a level of an external voltage, in response to the enable signal.

Still another embodiment includes an integrated circuit configured to select one of a plurality of reference voltages generated by dividing a power supply voltage to arrive at an input reference voltage in response to an enable signal, and change a level of the input reference voltage by an amount of change in a level of an external voltage, in response to the enable signal.

### BRIEF DESCRIPTION OF THE DRAWINGS

The above and other aspects, features and other advantages of the disclosed embodiments will be more clearly understood from the following detailed description taken in conjunction with the accompanying drawings, in which:

FIG. 1 is a block diagram of an integrated circuit in accordance with an embodiment of the present invention;

FIG. 2 is a circuit diagram of a reference voltage level setting unit of FIG. 1;

FIG. 3 is a diagram of a reference voltage generation unit of FIG. 1;

FIG. 4 is a circuit diagram of a reference voltage level compensation unit of FIG. 1; and

FIG. 5 is a block diagram of a data input unit of FIG. 1.

### DESCRIPTION OF SPECIFIC EMBODIMENTS

Hereinafter, embodiments of the present invention will be described with reference to accompanying drawings. However, the embodiments are for illustrative purposes only and are not intended to limit the scope of the invention.

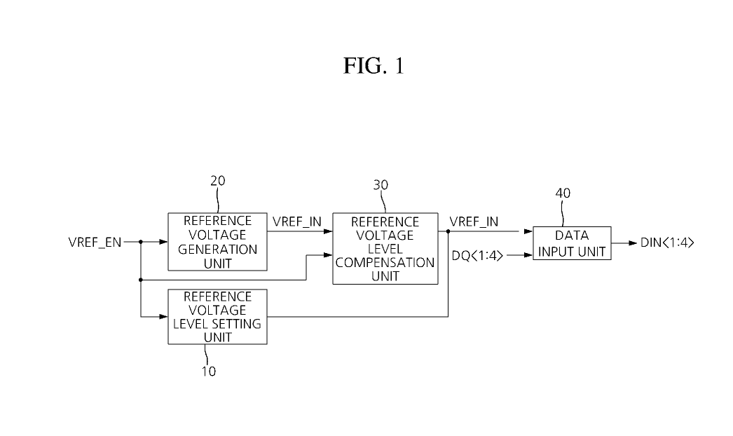

FIG. 1 is a block diagram of an integrated circuit in accordance with an embodiment of the present invention.

Referring to FIG. 1, the integrated circuit includes a reference voltage level setting unit 10, a reference voltage generation unit 20, a reference voltage level compensation unit 30, and a data input unit 40.

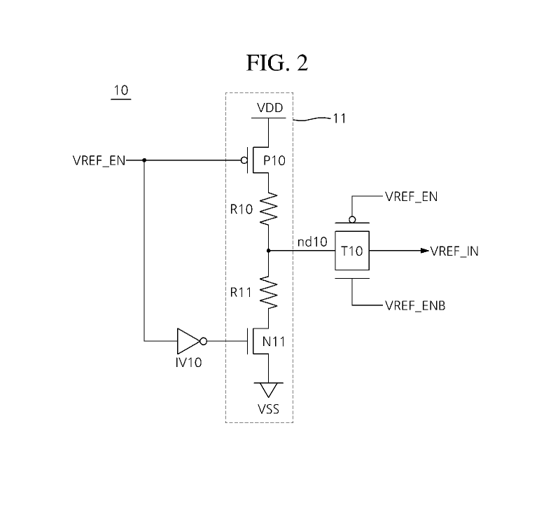

Referring to FIG. 2, the reference voltage level setting unit 10 includes a level setting section 11 and a transmission gate T10. The level setting section 11 includes a PMOS transistor P10, a resistor R10, an NMOS transistor N11, and a resistor R11. The PMOS transistor P10 and the resistor R10 are configured to pull-up drive a node nd10 in response to an enable signal VREF_EN, and the NMOS transistor N11 and the resistor R11 are configured to pull-down drive the node nd10 in response to the enable signal VREF_EN. The transmission gate T10 is configured to transmit a voltage of the node nd10 as an input reference voltage VREF_IN in response to the enable signal VREF_EN and the inverted signal VREF_ENB. Here, the enable signal VREF_EN has a logic low level during a power-up period, and changes to a high level after the power-up period.

The reference voltage level setting unit 10 drives the node nd10 to an intermediate level between a power supply voltage VDD and a ground voltage VSS according to the low-level enable signal VREF_EN during the power-up period, and transmits the voltage of the node nd10 as the input reference voltage VREF_IN. Meanwhile, after the power-up period, the level setting section 11 and the transmission gate T10 of the reference voltage level setting unit 10 are not driven because the enable signal VREF_EN has a logic high level after the power-up period.

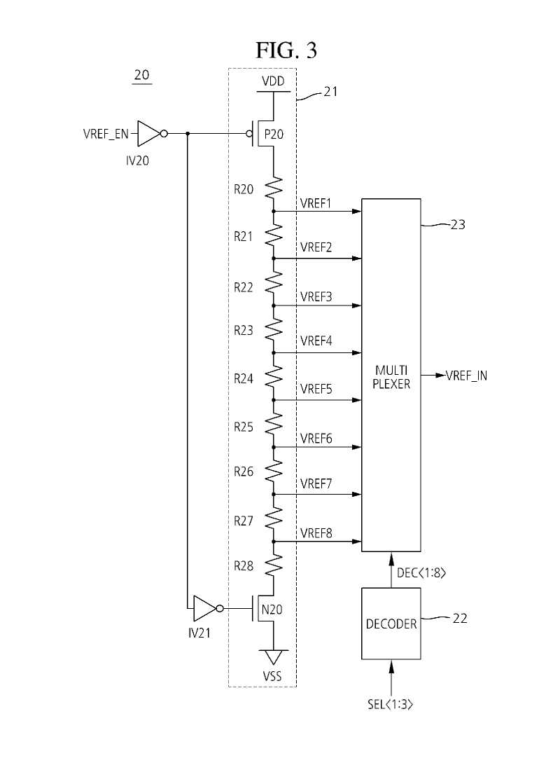

Referring to FIG. 3, the reference voltage generation unit 20 includes a voltage divider section 21, a decoder 22, and a multiplexer 23. The voltage divider section 21 includes an inverter IV20, an inverter IV21, a PMOS transistor P20, an NMOS transistor N20, and a plurality of resistors R20 to R28. The inverter IV20 is configured to invert and buffer the enable signal VREF_EN. The inverter IV21 is configured to invert and buffer an output of the inverter IV20. The PMOS transistor P20 and the NMOS transistor N20 are turned on when the enable signal VREF_EN is at a logic high level. The resistors R20 to R28 are configured to generate first to eighth reference voltages VREF1 to VREF8 by dividing the power supply voltage VDD. The decoder 22 is configured to decode first to third select signals SEL<1:3> and generate first to eighth decoded signals DEC<1:8> which are selectively enabled. Here, a combination of the first to eighth decoded signals DEC<1:8>, which are selectively enabled according to a logic level combination of the first to third select signals SEL<1:3> inputted from a memory controller or outside, may be set in various manners depending on embodiments. The multiplexer 23 is configured to select one of the first to eighth reference voltages VREF1 to VREF8 and output the selected signal as the input reference voltage VREF_IN, in response to the first to eighth decoded signals DEC<1:8>. The input reference voltage VREF_IN, according to the first to eighth decoded signals DEC<1:8>, may be set in various manners depending on embodiments.

In the reference voltage generation unit 20 configured in such a manner, the voltage divider section 21 is driven by the high level enable signal VREF_EN after the power-up period, and generates the first to eighth reference voltages VREF1 to VREF8. Furthermore, one of the first to eighth reference voltages VREF1 to VREF8 is outputted as the input reference voltage VREF_IN according to a logic level combination of the first to third select signals SEL<1:3>.

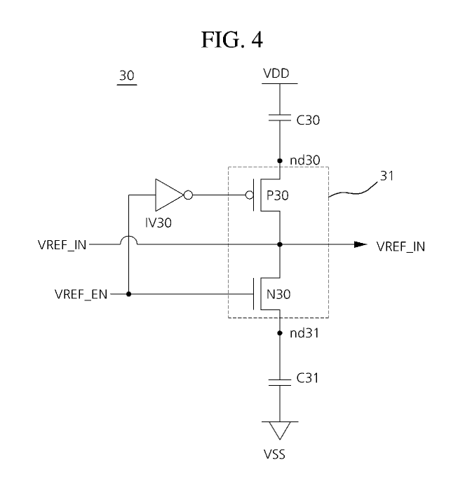

Referring to FIG. 4, the reference voltage level compensation unit 30 includes first and second capacitors C30 and C31 and a switch section 31. The first capacitor C30 is positioned between the power supply voltage VDD and a node nd30 and configured to change the voltage of the node nd30 by an amount of change in a level of the power supply voltage VDD. The second capacitor C31 is positioned between a node nd31 and the ground voltage VSS and configured to change the voltage of the node nd31 by an amount of change in a level the ground voltage VSS. The switch section 31 is positioned between the node nd30 and the node nd31, and configured to be turned on in response to the enable signal VREF_EN and change the level of the input reference voltage VREF_IN by an amount of change in voltage supplied by the nodes nd30 and nd31.

The reference voltage level compensation unit 30 changes the level of the input reference voltage VREF_IN by an amount of change in the level of the power supply voltage VDD and the ground voltage VSS after the power-up period.

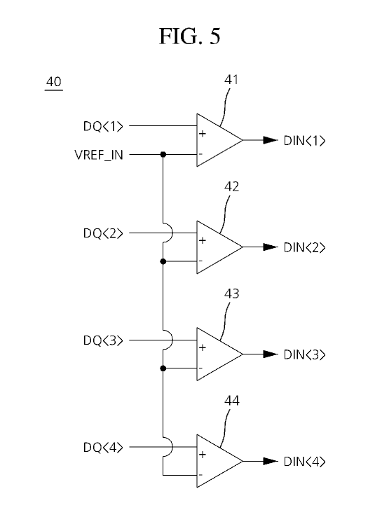

Referring to FIG. 5, the data input unit 40 includes first to fourth comparators 41 to 44. The first comparator 41 is configured to compare the input reference voltage VREF_IN with first data DQ<1> and generate first input data DIN<1>. The second comparator 42 is configured to compare the input reference voltage VREF_IN with second data DQ<2> and generate second input data DIN<2>. The third comparator 43 is configured to compare the input reference voltage VREF_IN with third data DQ<3> and generate third input data DIN<3>. The fourth comparator 44 is configured to compare the input reference voltage VREF_IN with fourth data DQ<4> and generate fourth input data DIN<4>. The first to fourth comparators 41 to 44 may include a differential amplifier circuit.

The data input unit 40 configured in such a manner buffers the first to fourth data DQ<1:4> to output as the first to fourth input data DIN<1:4> in response to the input reference voltage VREF_IN.

The operation of the integrated circuit in accordance with an embodiment of the present invention will be described. The following descriptions will be focused on a method of setting the level of the input reference voltage VREF_IN by changing the level of the input reference voltage VREF_IN by an amount of change in a level of external voltages VDD and VSS.

First, during the power-up period, the reference voltage level setting unit 10 drives the input reference voltage VREF_IN to an intermediate level between the power supply voltage and the ground voltage VSS, in response to the low-level enable signal VREF_EN. At this time, the voltage divider section 21 of the reference voltage generation unit 20 is not driven because the enable signal VREF_EN was generated at a logic low level. Therefore, during the power-up period, the input reference voltage VREF_IN is driven to a preset level that may be an intermediate level between the power supply voltage VDD and the ground voltage VSS by the reference voltage level setting unit 10.

After the power-up period has ended, the enable signal VREF_EN changes to a logic high level. Therefore, the voltage divider section 21 of the reference voltage generation unit 20 is driven by the high-level enable signal VREF_EN and generates the first to eighth reference voltages VREF1 to VREF8. Furthermore, one of the first to eighth reference voltages VREF1 to VREF8 is outputted as the input reference voltage VREF_IN, according to a logic level combination of the first to third select signals SEL<1:3>. That is, the input reference voltage VREF_IN is driven to one level of the first to eighth reference voltages VREF1 to VREF8. Furthermore, the first and second capacitors C30 and C31 of the reference voltage level compensation unit 30 change the level of the input reference voltage VREF_IN by an amount of change in the level of the external voltages VDD and VSS. At this time, since the input reference voltage VREF_IN was driven to an intermediate level between the power supply voltage VDD and the ground voltage VSS during the power-up period, the level may be quickly set. Furthermore, the level of the input reference voltage VREF_IN may be changed by the level change amounts of the external voltages VDD and VSS.

Since the integrated circuit configured in such a manner changes the level of the input reference voltage VREF_IN by the voltage level of the external voltages VDD and VSS, it is possible to substantially prevent an error in determining the logic level of a digital signal. Furthermore, since the first and second capacitors C30 and C31 for compensating for the level of the input reference voltage VREF_IN are coupled through the transistors P30 and N30, loading of the output terminal may be reduced, which makes it possible to reduce a time during which the input reference voltage VREF_IN approaches the set level.

The embodiments of the present invention have been disclosed above for illustrative purposes. Those skilled in the art will appreciate that various modifications, additions and substitutions are possible, without departing from the scope and spirit of the invention as disclosed in the accompanying claims.

What is claimed is:

1. An integrated circuit comprising:
a reference voltage generation unit configured to be driven in response to an enable signal, select one of a plurality of reference voltages generated by dividing a power supply voltage as an input reference voltage, and output the input reference voltage; and
a reference voltage level compensation unit configured to be driven in response to the enable signal and change a level of the input reference voltage by an amount of change in a level of an external voltage.

2. The integrated circuit of claim 1, wherein the enable signal comprises a signal which is enabled after a power-up period in which a level of the power supply voltage rises to a target voltage level.

3. The integrated circuit of claim 1, wherein the reference voltage generation unit comprises:
a voltage divider section configured to generate the plurality of reference voltages by dividing the power supply voltage in response to the enable signal;
a decoder configured to decode a select signal and generate a decoded signal which is selectively enabled; and
a multiplexer configured to select one of the reference voltages as the input reference voltage in response to the decoded signal and output the input reference voltage.

4. The integrated circuit of claim 1, wherein the reference voltage level compensation unit comprises:
a first capacitor positioned between the power supply voltage and a first node and configured to change a voltage level of the first node by an amount of change in the level of the power supply voltage;
a second capacitor positioned between a second node and a ground voltage and configured to change a voltage level of the second node by an amount of change in a level of the ground voltage; and
a switch section positioned between the first node and the second node and configured to be driven in response to the enable signal and change the level of the input reference voltage by an amount of change in the voltage level of the first and second nodes.

5. The integrated circuit of claim 1, further comprising:
a reference voltage level setting unit configured to set the input reference voltage to a preset level in response to the enable signal; and
a data input unit configured to buffer data and output the buffered data as input data in response to the input reference voltage.

6. The integrated circuit of claim 5, wherein the reference voltage level setting unit comprises:
a level setting section configured to set a third node to an intermediate level between the power supply voltage and the ground voltage in response to the enable signal; and
a transmission gate configured to transmit a voltage of the third node as the input reference voltage in response to the enable signal.

7. The integrated circuit of claim 5, wherein the data input unit comprises:
a first comparator configured to compare the input reference voltage with first data and generate first input data; and
a second comparator configured to compare the input reference voltage with second data and generate second input data.

8. An input reference voltage generating method comprising:
selecting one of a plurality of reference voltages generated by dividing a power supply voltage to arrive at an input reference voltage in response to an enable signal; and
changing a level of the input reference voltage by an amount of change in a level of an external voltage, in response to the enable signal.

9. The input reference voltage generating method of claim 8, wherein the enable signal is a signal which is enabled after a power-up period in which a level of the power supply voltage rises to a target voltage level.

10. The input reference voltage generating method of claim 9, further comprising selecting one of the plurality of reference voltages generated after the power-up period has ended.

11. The input reference voltage generating method of claim 10, further comprising selecting one of the plurality of reference voltages based on a select signal.

12. The input reference voltage generating method of claim 8, further comprising changing a level of the input reference voltage based on a level of two external voltages.

13. The input reference voltage generating method of claim 11, further comprising driving the input reference voltage to an intermediate level between the power supply voltage and ground voltage after the power-up period has ended.

14. An integrated circuit configured to select one of a plurality of reference voltages generated by dividing a power supply voltage to arrive at an input reference voltage in response to an enable signal, and change a level of the input reference voltage by an amount of change in a level of an external voltage, in response to the enable signal.

15. The integrated circuit of claim 14, wherein the enable signal comprises a signal which is enabled after a power-up period in which a level of the power supply voltage rises to a target voltage level.

16. The integrated circuit of claim 14, further comprising:
a reference voltage generation unit configured to be driven in response to the enable signal to select one of the plurality of reference voltages generated and output the input reference voltage; and
a reference voltage level compensation unit configured to be driven in response to the enable signal and change the level of the input reference voltage by an amount of change in the level of the external voltage.

17. The integrated circuit of claim 16, wherein the reference voltage generation unit comprises:
a voltage divider section configured to generate the plurality of reference voltages by dividing the power supply voltage in response to the enable signal;
a decoder configured to decode a select signal and generate a decoded signal which is selectively enabled; and
a multiplexer configured to select one of the reference voltages as the input reference voltage in response to the decoded signal and output the input reference voltage.

18. The integrated circuit of claim 16, wherein the reference voltage compensation unit comprises:
a first capacitor positioned between the power supply voltage and a first node and configured to change a voltage level of the first node by an amount of change in a level of the power supply voltage;
a second capacitor positioned between a second node and a ground voltage and configured to change a voltage level of the second node by an amount of change in the level of the ground voltage; and
a switch section positioned between the first node and the second node and configured to be driven in response to the enable signal and change the level of the input reference voltage by an amount of change in the voltage level of the first and second nodes.

19. The integrated circuit of claim 14, further comprising:
a reference voltage level setting unit configured to set the input reference voltage to a preset level in response to the enable signal; and
a data input unit configured to buffer data and output the buffered data as input data in response to the input reference voltage.

20. The integrated circuit of claim 19, wherein the reference voltage level setting unit comprises:
a level setting section configured to set a third node to an intermediate level between the power supply voltage and the ground voltage in response to the enable signal; and
a transmission gate configured to transmit a voltage of the third node as the input reference voltage in response to the enable signal.
